(19) United States
(12) Patent Application Publication
(10) Pub. No.: US 2015/0318256 A1
(43) Pub. Date: Nov. 5, 2015

(54) PACKAGING SUBSTRATE AND SEMICONDUCTOR PACKAGE HAVING THE SAME

(71) Applicant: Siliconware Precision Industries Co., Ltd., Taichung (TW)

(72) Inventors: Shih-Yu Chang, Taichung (TW); Kuo-Ching Tsai, Taichung (TW)

(21) Appl. No.: 14/461,880

(22) Filed: Aug. 18, 2014

(30) Foreign Application Priority Data
May 1, 2014 (TW) 103115688

(51) Int. Cl. H01L 23/00; H01L 23/31; H01L 23/498

(52) U.S. Cl. CPC H01L 24/17; H01L 23/49827; H01L 23/49838; H01L 23/3114; H01L 2224/17163; H01L 2924/3841; H01L 2224/16227

(57) ABSTRACT

A packaging substrate is provided, which includes: a laminated body; first, second and third conductive pads formed on a surface of the laminated body so as for conductive bumps to be respectively mounted thereon, wherein the third conductive pad is positioned outside of an area between projections of the conductive bumps on the first and second conductive pads on the surface of the laminated body; first, second and third conductive vias formed in the laminated body and electrically connected to the first, second and third conductive pads, respectively; and first, second and third internal conductive traces formed in the laminated body and electrically connected to the first, second and third conductive vias, respectively, thereby preventing bridging from occurring between the conductive bumps and the conductive traces and overcoming non-wetting of the conductive bumps caused by a solder mask layer.

### BACKGROUND OF THE INVENTION

1. Field of the Invention

The present invention relates to packaging substrates and semiconductor packages, and more particularly, to a bump on trace type packaging substrate and a semiconductor package having the bump on trace packaging substrate.

2. Description of Related Art

As intelligent electronic devices become more and more popular, more multi-functional chips having high density I/O counts are increasingly needed. Accordingly, flip-chip technologies have been developed.

FIGS. 1A and 1A′ are schematic top and cross-sectional views of a conventional flip-chip packaging substrate. Referring to FIGS. 1A and 1A′, the packaging substrate has a laminated body 10 having opposite first and second surfaces. A first conductive pad 11a, a second conductive pad 11b and a third conductive pad 11c are formed on the first surface of the laminated body 10. The first, second and third conductive pads 11a, 11b, 11c can have a line shape, a circular shape, a long octagonal shape or a regular octagonal shape. A first surface conductive trace 16a, a second surface conductive trace 16b and a third surface conductive trace 16c are formed on the first surface of the laminated body 10 and are respectively electrically connected to the first, second and third conductive pads 11a, 11b, 11c through one ends thereof. The other ends of the first, second and third surface conductive traces 16a, 16b, 16c are respectively electrically connected to a first conductive via (not shown), a second conductive via (not shown) and a third conductive via 17c that are formed in the laminated body 10. Further, the conductive vias can be electrically connected through internal conductive traces 18 to the second surface of the laminated body 10 or directly penetrate through the laminated body 10. Furthermore, a plurality of external conductive traces or fourth conductive pads 12 can be formed on the second surface of the laminated body 10 and electrically connected to the conductive vias. In addition, solder balls 19 can be formed on the fourth conductive pads 12.

A plurality of conductive bumps 14 are respectively mounted on the first, second and third conductive pads 11a, 11b, 11c for external electrical connection. As the conductive bumps 14 are arranged in a high density, the third surface conductive trace 16c may extend between the conductive bumps 14 of the first conductive pad 11a and the second conductive pad 11b. However, if the space P between the conductive bumps 14 of the first conductive pad 11a and the second conductive pad 11b is too small, for example, less than 40 um, bridging easily occurs between the third surface conductive trace 16c and the conductive bumps 14 during reflow of the conductive bumps 14, thus incurring a short circuit and reducing the flip-chip bonding quality.

To overcome the above-described drawback, an improved flip-chip packaging substrate is provided. Referring to FIG. 1B, a solder mask layer 15 is formed on the surface of the laminated body 10 between the first conductive pad 11a and the second conductive pad 11b so as to cover the third surface conductive trace 16c, thereby preventing bridging from occurring between the third surface conductive trace 16c and the conductive bumps 14 and hence avoiding a short circuit and increasing the flip-chip bonding quality. However, the solder mask layer 15 has a thickness greater than that of the third surface conductive trace 16c. If the solder mask layer 15 is formed with a positional error, the solder mask layer 15 will become too close to the first conductive pad 11a or the second conductive pad 11b. As such, the conductive bump 14 will abut against the solder mask layer 15 and cannot come into contact with the first conductive pad 11a or the second conductive pad 11b, thus leading to non-wetting of the conductive bump 14 and reducing the flip-chip bonding quality.

Therefore, how to overcome the above-described drawbacks has become critical.

### SUMMARY OF THE INVENTION

In view of the above-described drawbacks, the present invention provides a packaging substrate, which comprises: a laminated body; first, second and third conductive pads formed on a surface of the laminated body so as for conductive bumps to be respectively mounted thereon, wherein the conductive bumps have a maximum width greater than or equal to the width of the first, second and third conductive pads, the third conductive pad being positioned outside of an area between projections of the conductive bumps on the first and second conductive pads on the surface of the laminated body; first, second and third conductive vias formed in the laminated body and electrically connected to the first, second and third conductive pads, respectively; and first, second and third internal conductive traces formed in the laminated body and electrically connected to the first, second and third conductive vias, respectively.

The present invention further provides a semiconductor package, which comprises: a laminated body; first, second and third conductive pads formed on a surface of the laminated body; a plurality of conductive bumps mounted on the first, second and third conductive pads, respectively, wherein the conductive bumps have a maximum width greater than or equal to the width of the first, second and third conductive pads, the third conductive pad being positioned outside of an area between projections of the conductive bumps on the first and second conductive pads on the surface of the laminated body; first, second and third conductive vias formed in the laminated body and electrically connected to the first, second and third conductive pads, respectively; first, second and third internal conductive traces formed in the laminated body and electrically connected to the first, second and third conductive vias, respectively; and at least a chip disposed on the conductive bumps.

The present invention provides another packaging substrate, which comprises: a laminated body; first, second and third conductive pads formed on a surface of the laminated body so as for conductive bumps to be respectively mounted thereon, wherein the first, second and third conductive pads have a width greater than the maximum width of the conductive bumps and less than two times the maximum width of the conductive bumps, the third conductive pad being positioned outside of an area between projections of the conductive bumps on the first and second conductive pads on the surface of the laminated body; first, second and third conductive vias formed in the laminated body and electrically connected to the first, second and third conductive pads, respectively; and first, second and third internal conductive traces formed in the laminated body and electrically connected to the first, second and third conductive vias, respectively.

The present invention provides another semiconductor package, which comprises: a laminated body; first, second and third conductive pads formed on a surface of the laminated body; a plurality of conductive bumps mounted on the first, second and third conductive pads, respectively, wherein the first, second and third conductive pads have a width greater than the maximum width of the conductive bumps and less than two times the maximum width of the conductive bumps, the third conductive pad being positioned outside of an area between projections of the conductive bumps on the first and second conductive pads on the surface of the laminated body; first, second and third conductive vias formed in the laminated body and electrically connected to the first, second and third conductive pads, respectively; first, second and third internal conductive traces formed in the laminated body and electrically connected to the first, second and third conductive vias, respectively; and at least a chip disposed on the conductive bumps.

According to the present invention, the conductive pads are formed on the surface of the laminated body for mounting conductive bumps and the conductive traces are formed in the laminated body for electrical signal transmission. As such, the third conductive pad can be positioned outside of the area between the projections of the conductive bumps on the first and second conductive pads on the surface of the laminated body. Therefore, the present invention prevents bridging from occurring between the conductive traces and the conductive bumps that are arranged in a high density. Further, by dispensing with the solder mask layer between the conductive bumps of the first and second conductive pads, the present invention overcomes the conventional drawback of non-wetting of the conductive bumps.

### BRIEF DESCRIPTION OF DRAWINGS

FIGS. 1A and 1A′ are schematic top and cross-sectional views of a conventional flip-chip packaging substrate;

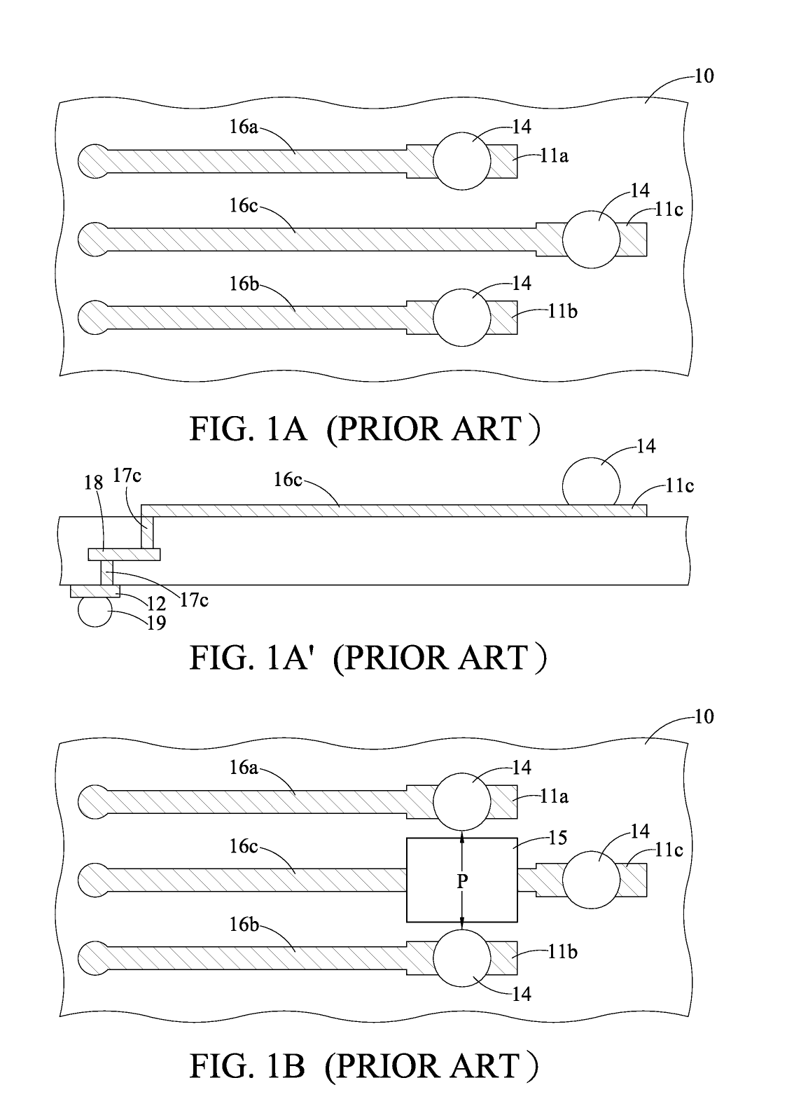

FIG. 1B is a schematic top view of another conventional flip-chip packaging substrate;

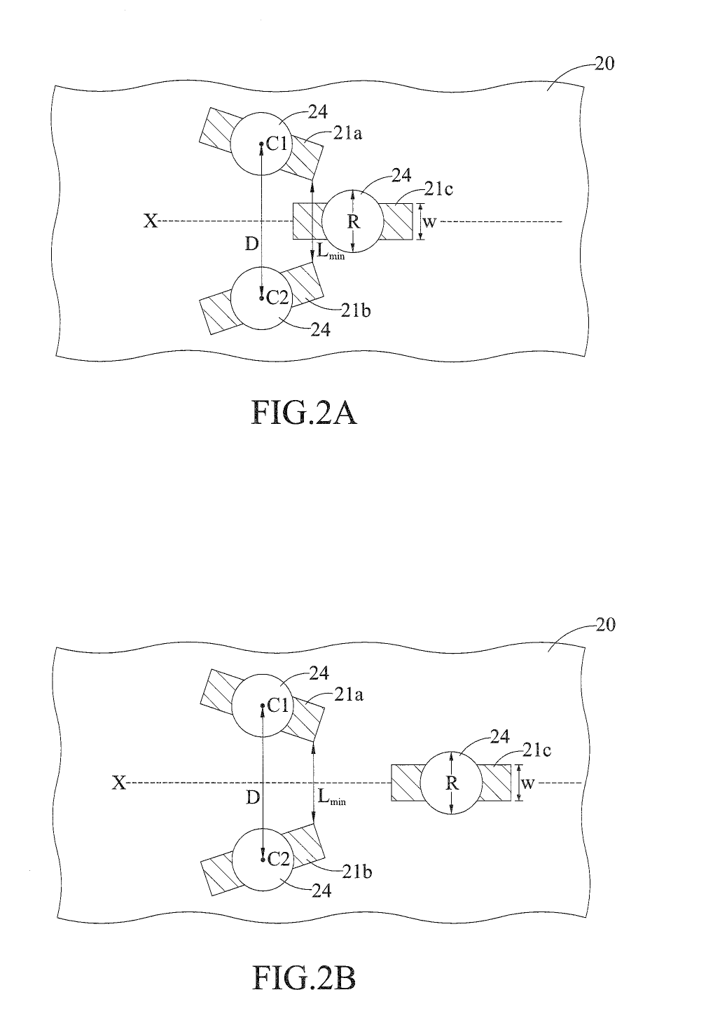

FIGS. 2A to 2E are schematic top views showing different embodiments of a packaging substrate of the present invention;

FIG. 2′ is a schematic cross-sectional view taken at a position where a minimum distance is formed between a first conductive pad and a second conductive pad of FIGS. 2A to 2E;

FIG. 3 is a schematic cross-sectional view of a semiconductor package of the present invention;

FIGS. 4A to 4C are schematic top views showing different embodiments of a packaging substrate of the present invention;

FIG. 4′ is a schematic cross-sectional view taken at a position where a minimum distance is formed between a first conductive pad and a second conductive pad of FIGS. 4A to 4C; and

FIG. 5 is a schematic cross-sectional view of a semiconductor package according to another embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

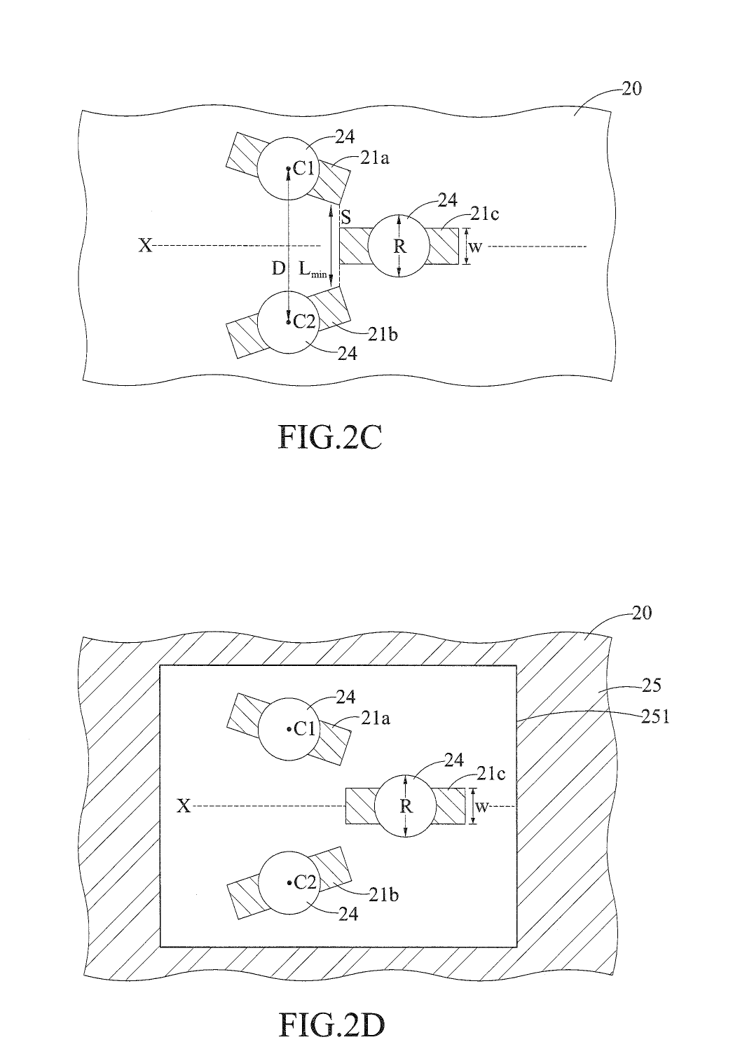

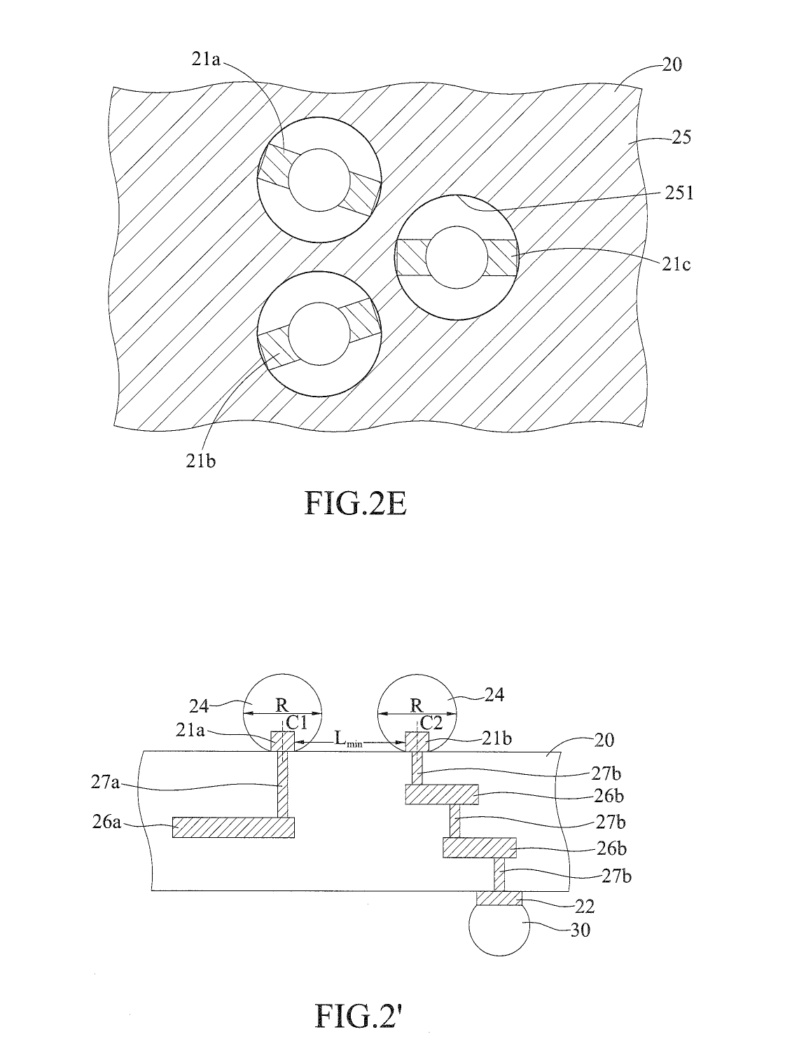

FIGS. 2A to 2E are schematic top views showing different embodiments of a packaging substrate of the present invention and FIG. 2′ is a schematic cross-sectional view taken at a position where a minimum distance is formed between a first conductive pad and a second conductive pad of FIGS. 2A to 2E.

Referring to FIGS. 2A to 2E and FIG. 2′, the packaging substrate has: a laminated body 20; a first conductive pad 21a, a second conductive pad 21b and a third conductive pad 21c formed on a surface of the laminated body 20; a first internal conductive trace 26a, a second internal conductive trace 26b and a third internal conductive trace (not shown) formed in the laminated body 20; and a first conductive via 27a, a second conductive via 27b and a third conductive via (not shown) formed in the laminated body 20 for electrically connecting the first, second and third conductive pads 21a, 21b, 21c to the first, second and third internal conductive traces, respectively.

Referring to FIG. 2A, the laminated body 20 can be made of, but not limited to, PPG or ABF (Ajinomoto Build-up Film).

The first, second and third conductive pads 21a, 21b, 21c are formed on the surface of the laminated body 20 so as for conductive bumps 24 to be respectively mounted thereon. The first, second and third conductive pads 21a, 21b, 21c can have a line shape, a circular shape, a long octagonal shape or a regular octagonal shape. The maximum width R of the conductive bumps 24 is greater than or equal to the width of the first, second and third conductive pads 21a, 21b, 21c. If the first and second conductive pads 21a, 21b have a line shape or a long octagonal shape, the length of the first and second conductive pads 21a, 21b is less than or equal to two times the maximum width R of the conductive bumps 24. Further, the third conductive pad 21c is positioned outside of an area between projections of the conductive bumps 24 on the first and second conductive pads 21a, 21b on the surface of the laminated body 20. In addition, the first and second conductive pads 21a, 21b are positioned at two sides of a fictitious center line X.

In particular, the conductive bumps 24 can be mounted on the first, second and third conductive pads 21a, 21b, 21c, respectively. Alternatively, the conductive bumps 24 can be formed on a chip. As such, when the chip is mounted on the packaging substrate, the conductive bumps 24 can be mounted on the first, second and third conductive pads 21a, 21b, 21c through a reflow process. For example, the first and second conductive pads 21a, 21b can be positioned at the two sides of the fictitious center line X. The arrangement of the first and second conductive pads 21a, 21b relative to the fictitious center line X can be determined according to the design. For example, the first and second conductive pads 21a, 21b can be symmetrically arranged relative to the fictitious center line X so as to be mirrored to one another. Therefore, the first and second conductive pads 21a, 21b are aligned with one another along the fictitious center line X.

Further, the conductive bumps of the present invention generally have a high density and are separate from each other. Therefore, the distance D between the geometrical center C1 of the first conductive pad 21a and the geometrical center C2 of the second conductive pad 21b is in a range between the maximum width R of the conductive bumps 24 and two times the maximum width R of the conductive bumps 24. As such, the conductive bumps 24 mounted on the geometrical centers C1 and C2 do not come into contact with one another. Further, the third conductive pad 21c is positioned outside of the area of the projections of the conductive bumps 24 on the first and second conductive pads 21a, 21b on the surface of the laminated body 20. In particular, the first, second and third conductive pads 21a, 21b, 21c are arranged in an alternate staggering pattern. That is, the third conductive pad 21c is positioned at one side of the line connecting the geometrical centers C1 and C2 of the first and second conductive pads 21a, 21b. To prevent the first conductive pad 21a and the second conductive pad 21b from coming into contact with one another, the minimum distance Lₘᵢₙ between edges of the first conductive pad 21a and the second conductive pad 21b is greater than zero. Further, to achieve a high density arrangement of the conductive bumps 24 and prevent a positional error when the conductive bump 24 is mounted on the third conductive pad 21c, the minimum distance Lₘᵢₙ is less than two times the maximum width R of the conductive bump 24. Preferably, to prevent the third conductive pad 21c from coming into contact with the first and second conductive pads 21a, 21b, the minimum distance Lₘᵢₙ between the first and second conductive pads 21a, 21b is greater than the width of the third conductive pad 21 (i.e., line width w).

FIG. 2B is a schematic top view showing another embodiment of the packaging substrate of the present invention. The present embodiment differs from the embodiment of FIG. 2A in that the third conductive pad 21c is positioned outside of an area between the first and second conductive pads 21a, 21b.

FIG. 2C is a schematic top view showing a further embodiment of the packaging substrate of the present invention. Different from FIG. 2A, an edge of the third conductive pad 21c of the present embodiment is positioned along a line S connecting two end points of the first and second conductive pads 21a, 21b that are closest to one another.

FIG. 2D is a schematic top view showing another embodiment of the packaging substrate of the present invention. In the present embodiment, an insulating layer 25, such as a solder mask layer, is formed on the surface of the laminated body 20 and has an opening 251 exposing the first, second and third conductive pads 21a, 21b, 21c.

FIG. 2E is a schematic top view showing a further embodiment of the packaging substrate of the present invention. Different from FIG. 2D, the insulating layer 25 of the present embodiment has a plurality of openings 251. As such, the first, second and third conductive pads 21a, 21b, 21c are partially exposed from the respective openings 251. Referring to FIG. 2′, the first conductive via 27a, the second conductive via 27b and the third conductive via (not shown) are formed in the laminated body 20 and electrically connected to the first conductive pad 21a, the second conductive pad 21b and the third conductive pad 21c, respectively. The first internal conductive trace 26a, the second internal conductive trace 26b and the third internal conductive trace are formed in the laminated body 20 and electrically connected to the first conductive via 27a, the second conductive via 27b and the third conductive via, respectively. The first internal conductive trace 26a, the second internal conductive trace 26b and the third internal conductive trace are used for electrical signal transmission. Since it is well known in the art, detailed description thereof is omitted herein. The first internal conductive trace 26a, the second internal conductive trace 26b and the third internal conductive trace can be formed at the same or different depths in the laminated body 20. For example, the first internal conductive trace 26a can be formed at a certain depth in the laminated body 20 and turns its direction in a plane at the certain depth in the laminated body 20. On the other hand, both the second internal conductive trace 26b and the second conductive via 27b have a plurality of portions formed at different depth. The second internal conductive trace 26b can turn its direction at different depth in the same sectional plane. The portions of the second conductive via 27b at different depth are electrically connected to the corresponding portions of the second internal conductive trace 26b. Thereby, the second conductive via 27b is electrically connected to an external conductive trace or a fourth conductive pad 22 formed on the other surface of the laminated body 20. A solder ball 30 is formed on the external conductive trace or the fourth conductive pad 22. Therefore, although the laminated body 20 has a limited area, the prevent invention allows the conductive traces to be easily arranged in the laminated body 20. Further, the first internal conductive trace 26a is electrically connected to the first conductive pad 21a through the first conductive via 27a for electrical signal transmission.

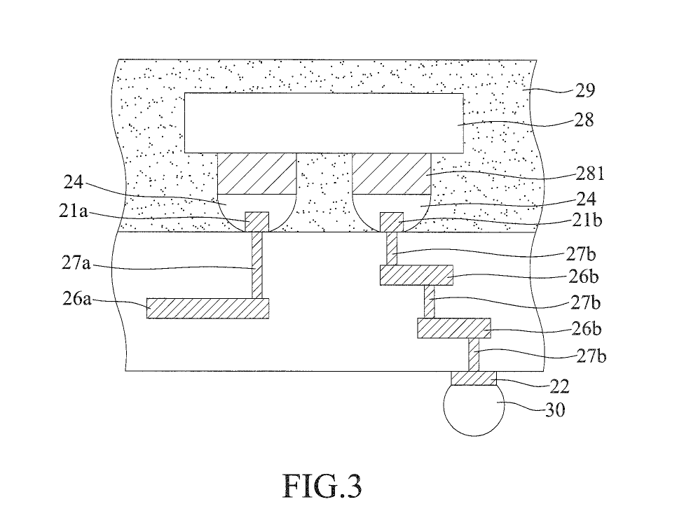

FIG. 3 is a schematic cross-sectional view of a semiconductor package of the present invention.

Referring to FIG. 3, the semiconductor package has: a laminated body 20; a first conductive pad 21a, a second conductive pad 21b and a third conductive pad (not shown) formed on a surface of the laminated body 20; a first conductive via 27a, a second conductive via 27b and a third conductive via (not shown) formed in the laminated body 20 and electrically connected to the first conductive pad 21a, the second conductive pad 21b and the third conductive pad, respectively; a first internal conductive trace 26a, a second internal conductive trace 26b and a third internal conductive trace (not shown) formed in the laminated body 20 and electrically connected to the first conductive via 27a, the second conductive via 27b and the third conductive via, respectively; a plurality of conductive bumps 24 mounted on the first conductive pad 21a, the second conductive pad 21b and the third conductive pad, respectively; and at least a chip 28 disposed on the conductive bumps 24. The laminated body 20, the first, second and third conductive pads, the first, second and third conductive vias, the first, second and third internal conductive traces and the conductive bumps are the same as described in FIGS. 2A to 2E and FIG. 2′ and not detailed herein.

The chip 28 has a plurality of conductive posts 281 formed on a surface thereof. The conductive posts 281 can be copper posts. For example, by performing a reflow process, the conductive posts 281 of the chip 28 are mounted on the conductive bumps 24. Alternatively, the conductive bumps 24 are formed on the conductive posts 281 of the chip 28 and the chip 28 is electrically connected to the first, second and third conductive pads through the conductive bumps 24 on the conductive posts 281.

In an embodiment, as shown in FIG. 2D, an insulating layer 25 can be formed on the surface of the laminated body 20 and has an opening 251 exposing the first, second and third conductive pads 21a, 21b 21c.

In another embodiment, as shown in FIG. 2E, the insulating layer 25 has a plurality of openings 251 and the first, second and third conductive pads 21a, 21b 21c are partially exposed from the respective openings 251.

The semiconductor package further has an encapsulant 29 formed on the surface of the laminated body 20 for encapsulating the chip 28 and the conductive bumps 24.

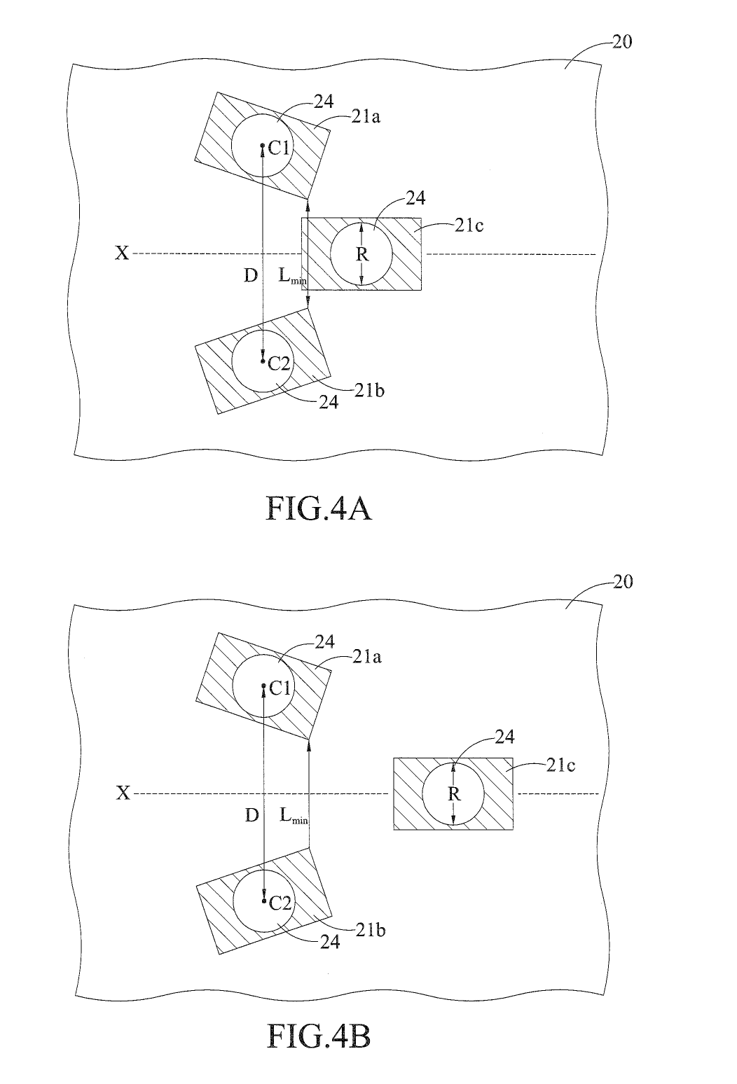

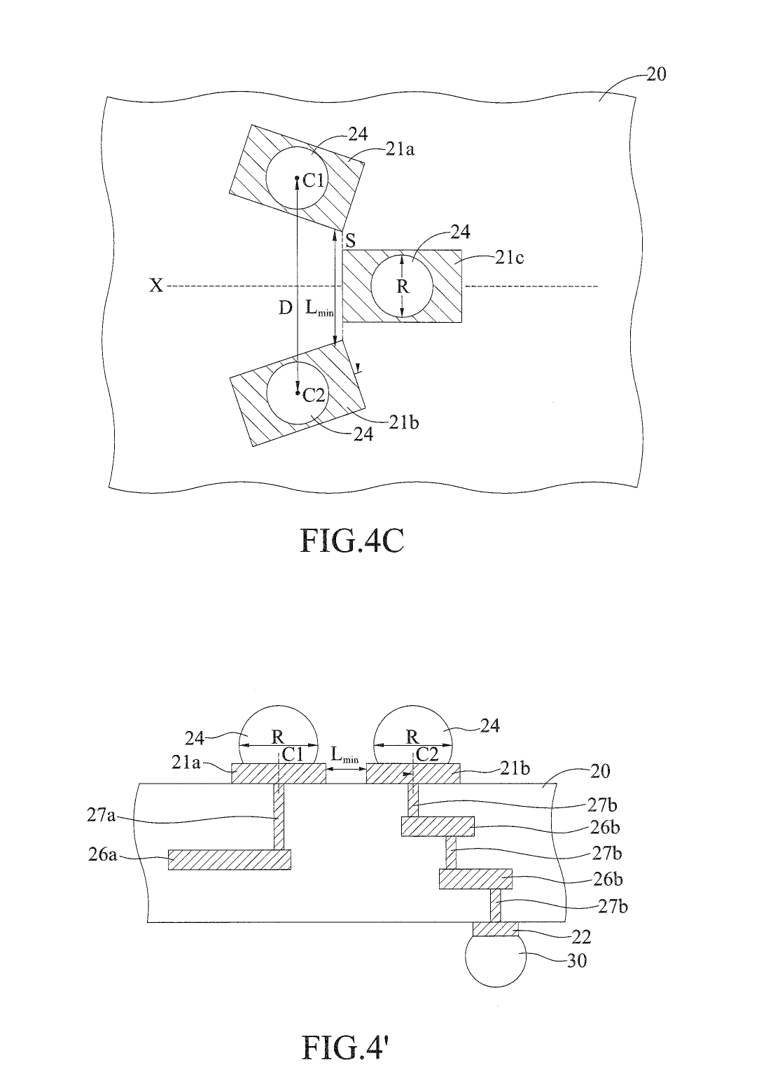

FIGS. 4A to 4C are schematic top views showing different embodiments of a packaging substrate of the present invention, and FIG. 4′ is a schematic cross-sectional view taken at a position where a minimum distance is formed between a first conductive pad and a second conductive pad of FIGS. 4A to 4C.

Referring to FIGS. 4A to 4C and FIG. 4′, the packaging substrate has: a laminated body 20; a first conductive pad 21a, a second conductive pad 21b and a third conductive pad 21c formed on a surface of the laminated body 20; a first internal conductive trace 26a, a second internal conductive trace 26b and a third internal conductive trace (not shown) formed in the laminated body 20; and a first conductive via 27a, a second conductive via 27b and a third conductive via (not shown) formed in the laminated body 20 for electrically connecting the first, second and third conductive pads 21a, 21b, 21c to the first, second and third internal conductive traces, respectively.

The laminated body 20 is the same as described in FIG. 2A and not detailed herein. Referring to FIG. 4A, the first, second and third conductive pads 21a, 21b, 21c are formed on the surface of the laminated body 20 so as for conductive bumps 24 to be respectively mounted thereon. The first, second and third conductive pads 21a, 21b, 21c can have a line shape, a circular shape, a long octagonal shape or a regular octagonal shape. The width of the first, second and third conductive pads 21a, 21b, 21c is greater than the maximum width R of the conductive bumps 24 and less than two times the maximum width R of the conductive bumps 24. If the first and second conductive pads 21a, 21b have a line shape or a long octagonal shape, the length of the first and second conductive pads 21a, 21b is less than or equal to two times the maximum width R of the conductive bumps 24. If the first, second and third conductive pads 21a, 21b, 21c have a circular shape, the area of the first, second and third conductive pads 21a, 21b, 21c is greater than the projection area of the conductive bumps 24 on the surface of the laminated body 20 and less than two times the projection area of the conductive bumps 24 on the surface of the laminated body 20. Further, the third conductive pad 21c is positioned outside of an area between projections of the conductive bumps 24 on the first and second conductive pads 21a, 21b on the surface of the laminated body 20. In particular, the first, second and third conductive pads 21a, 21b, 21c can be arranged in an alternate staggering pattern. Further, the first and second conductive pads 21a, 21b are positioned at two sides of a fictitious center line X.

In particular, the conductive bumps 24 can be mounted on the first, second and third conductive pads 21a, 21b, 21c, respectively. Alternatively, the conductive bumps 24 can be formed on a chip 28. As such, when the chip 28 is mounted on the packaging substrate, the conductive bumps 24 can be mounted on the first, second and third conductive pads 21a, 21b, 21c through a reflow process. For example, the first and second conductive pads 21a, 21b can be positioned at the two sides of the fictitious center line X. The arrangement of the first and second conductive pads 21a, 21b relative to the fictitious center line X can be determined according to the design. For example, the first and second conductive pads 21a, 21b can be symmetrically arranged relative to the fictitious center line X so as to be mirrored to one another. Therefore, the first and second conductive pads 21a, 21b are aligned with one another along the fictitious center line X.

Further, the conductive bumps of the present invention generally have a high density and are separate from each other. Therefore, the distance D between the geometrical center C1 of the first conductive pad 21a and the geometrical center C2 of the second conductive pad 21b is in a range between half of the sum of the maximum widths of the first and second conductive pads 21a, 21b and the sum of the maximum widths of the first and second conductive pads 21a, 21b. As such, the conductive bumps 24 mounted on the geometrical centers C1 and C2 do not come into contact with one another. Further, the third conductive pad 21c is positioned outside of the area of the projections of the conductive bumps 24 on the first and second conductive pads 21a, 21b on the surface of the laminated body 20. To prevent the first conductive pad 21a and the second conductive pad 21b from coming into contact with one another, the minimum distance Lₘᵢₙ between edges of the first conductive pad 21a and the second conductive pad 21b is greater than zero and less than two times the width of the third conductive pad 21c.

FIG. 4B is a schematic top view showing another embodiment of the packaging substrate of the present invention. The present embodiment differs from the embodiment of FIG. 4A in that the third conductive pad 21c is positioned outside of an area between the first and second conductive pads 21a, 21b.

FIG. 4C is a schematic top view showing a further embodiment of the packaging substrate of the present invention. Different from FIG. 4A, an edge of the third conductive pad 21c of the present embodiment is positioned along a line S connecting two end points of the first and second conductive pads 21a, 21b that are closest to one another.

In an embodiment, an insulating layer, such as a solder mask layer, can further be formed on the surface of the laminated body 20 and have an opening exposing the first, second and third conductive pads 21a, 21b, 21c.

In another embodiment, the insulating layer has a plurality of openings. As such, the first, second and third conductive pads 21a, 21b, 21c are partially exposed from the respective openings 251.

FIG. 4′ is a schematic cross-sectional view taken at a position where a minimum distance is formed between the first conductive pad and the second conductive pad of FIGS. 4A to 4C. The present embodiment differs from the embodiment of FIG. 2′ in the relationship between the conductive bumps 24 and the first, second and third conductive pads. Since the relationship between the conductive bumps 24 and the first, second and third conductive pads is described in FIGS. 4A to 4C, it is not detailed herein.

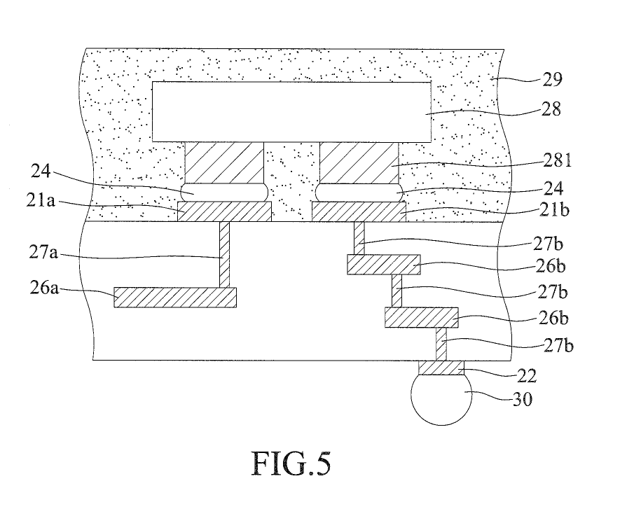

FIG. 5 is a schematic cross-sectional view of a semiconductor package according to another embodiment of the present invention. The present embodiment differs from the embodiment of FIG. 3 in the relationship between the conductive bumps 24 and the first, second and third conductive pads as described in FIGS. 4A to 4C.

According to the present invention, the conductive pads are formed on the surface of the laminated body for mounting conductive bumps and the conductive traces are formed in the laminated body for electrical signal transmission. As such, the third conductive pad can be positioned outside of the area between the projections of the conductive bumps on the first and second conductive pads on the surface of the laminated body. Therefore, the present invention prevents bridging from occurring between the conductive traces and the conductive bumps that are arranged in a high density. Further, by dispensing with the solder mask layer between the conductive bumps of the first and second conductive pads, the present invention overcomes the conventional drawback of non-wetting of the conductive bumps.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A packaging substrate, comprising:
a laminated body;
first, second and third conductive pads formed on a surface of the laminated body so as for conductive bumps to be respectively mounted thereon, wherein the conductive bumps have a maximum width greater than or equal to the width of the first, second and third conductive pads, the third conductive pad being positioned outside of an area between projections of the conductive bumps on the first and second conductive pads on the surface of the laminated body;
first, second and third conductive vias formed in the laminated body and electrically connected to the first, second and third conductive pads, respectively; and
first, second and third internal conductive traces formed in the laminated body and electrically connected to the first, second and third conductive vias, respectively.

2. The packaging substrate of claim 1, wherein the first, second and third conductive pads are arranged in an alternate staggering pattern.

3. The packaging substrate of claim 1, wherein a minimum distance between edges of the first and second conductive pads is less than two times the maximum width of the conductive bumps.

4. The packaging substrate of claim 3, wherein the minimum distance between the edges of the first and second conductive pads is greater than the width of the third conductive pad.

5. The packaging substrate of claim 1, wherein the laminated body is made of PPG or ABF (Ajinomoto Build-up Film).

6. The packaging substrate of claim 1, wherein the first, second and third conductive pads have a line shape, a circular shape, a long octagonal shape or a regular octagonal shape.

7. The packaging substrate of claim 6, wherein the first and second conductive pads have a line shape or a long octagonal shape and have a length less than or equal to two times the maximum width of the conductive bumps.

8. The packaging substrate of claim 1, wherein the third conductive pad is positioned outside of an area between the first and second conductive pads.

9. The packaging substrate of claim 8, wherein an edge of the third conductive pad is positioned along a line connecting two end points of the first and second conductive pads closest to one another.

10. A semiconductor package, comprising:
a laminated body;
first, second and third conductive pads formed on a surface of the laminated body;
a plurality of conductive bumps mounted on the first, second and third conductive pads, respectively, wherein the conductive bumps have a maximum width greater than or equal to the width of the first, second and third conductive pads, the third conductive pad being positioned outside of an area between projections of the conductive bumps on the first and second conductive pads on the surface of the laminated body;
first, second and third conductive vias formed in the laminated body and electrically connected to the first, second and third conductive pads, respectively;
first, second and third internal conductive traces formed in the laminated body and electrically connected to the first, second and third conductive vias, respectively; and
at least a chip disposed on the conductive bumps.

11. The semiconductor package of claim 10, wherein the first, second and third conductive pads are arranged in an alternate staggering pattern.

12. The semiconductor package of claim 10, wherein a minimum distance between edges of the first and second conductive pads is less than two times the maximum width of the conductive bumps.

13. The semiconductor package of claim 12, wherein the minimum distance between the edges of the first and second conductive pads is greater than the width of the third conductive pad.

14. The semiconductor package of claim 10, wherein the laminated body is made of PPG or ABF (Ajinomoto Build-up Film).

15. The semiconductor package of claim 10, wherein the first, second and third conductive pads have a line shape, a circular shape, a long octagonal shape or a regular octagonal shape.

16. The semiconductor package of claim 15, wherein the first and second conductive pads have a line shape or a long octagonal shape and have a length less than or equal to two times the maximum width of the conductive bumps.

17. The semiconductor package of claim 10, wherein the third conductive pad is positioned outside of an area between the first and second conductive pads.

18. The semiconductor package of claim 17, wherein an edge of the third conductive pad is positioned along a line connecting two end points of the first and second conductive pads closest to one another.

19. The semiconductor package of claim 10, wherein a plurality of conductive posts are formed on the chip for electrically connecting the chip to the conductive bumps.

20. The semiconductor package of claim 10, further comprising an encapsulant formed on the surface of the laminated body for encapsulating the chip and the conductive bumps.

21. A packaging substrate, comprising:
a laminated body;
first, second and third conductive pads formed on a surface of the laminated body so as for conductive bumps to be respectively mounted thereon, wherein the first, second and third conductive pads have a width greater than the maximum width of the conductive bumps and less than two times the maximum width of the conductive bumps, the third conductive pad being positioned outside of an area between projections of the conductive bumps on the first and second conductive pads on the surface of the laminated body;
first, second and third conductive vias formed in the laminated body and electrically connected to the first, second and third conductive pads, respectively; and
first, second and third internal conductive traces formed in the laminated body and electrically connected to the first, second and third conductive vias, respectively.

22. The packaging substrate of claim 21, wherein the first, second and third conductive pads are arranged in an alternate staggering pattern.

23. The packaging substrate of claim 21, wherein a minimum distance between edges of the first and second conductive pads is less than two times the width of the third conductive pad.

24. The packaging substrate of claim 21, further comprising an insulating layer formed on the surface of the laminated body and having a plurality of openings for exposing the first, second and third conductive pads.

25. The packaging substrate of claim 21, wherein the laminated body is made of PPG or ABF (Ajinomoto Build-up Film).

26. The packaging substrate of claim 21, wherein the first, second and third conductive pads have a line shape, a circular shape, a long octagonal shape or a regular octagonal shape.

27. The packaging substrate of claim 26, wherein the first and second conductive pads have a line shape or a long octagonal shape and have a length less than or equal to two times the maximum width of the conductive bumps.

28. The packaging substrate of claim 26, wherein the first, second and third conductive pads have a circular shape, and the area of the first, second and third conductive pads is greater than the projection area of the conductive bumps on the surface of the laminated body and less than two times the projection area of the conductive bumps on the surface of the laminated body.

29. The packaging substrate of claim 21, wherein the third conductive pad is positioned outside of an area between the first and second conductive pads.

30. The packaging substrate of claim 29, wherein an edge of the third conductive pad is positioned along a line connecting two end points of the first and second conductive pads closest to one another.

31. A semiconductor package, comprising:
a laminated body;
first, second and third conductive pads formed on a surface of the laminated body;
a plurality of conductive bumps mounted on the first, second and third conductive pads, respectively, wherein the first, second and third conductive pads have a width greater than the maximum width of the conductive bumps and less than two times the maximum width of the conductive bumps, the third conductive pad being positioned outside of an area between projections of the conductive bumps on the first and second conductive pads on the surface of the laminated body;
first, second and third conductive vias formed in the laminated body and electrically connected to the first, second and third conductive pads, respectively;
first, second and third internal conductive traces formed in the laminated body and electrically connected to the first, second and third conductive vias, respectively; and
at least a chip disposed on the conductive bumps.

32. The semiconductor package of claim 31, wherein the first, second and third conductive pads are arranged in an alternate staggering pattern.

33. The semiconductor package of claim 31, wherein a minimum distance between edges of the first and second conductive pads is less than two times the width of the third conductive pad.

34. The semiconductor package of claim 31, wherein the laminated body is made of PPG or ABF (Ajinomoto Build-up Film).

35. The semiconductor package of claim 31, wherein the first, second and third conductive pads have a line shape, a circular shape, a long octagonal shape or a regular octagonal shape.

36. The semiconductor package of claim 35, wherein the first and second conductive pads have a line shape or a long octagonal shape and have a length less than or equal to two times the maximum width of the conductive bumps.

37. The semiconductor package of claim 35, wherein the first, second and third conductive pads have a circular shape, and the area of the first, second and third conductive pads is greater than the projection area of the conductive bumps on the surface of the laminated body and less than two times the projection area of the conductive bumps on the surface of the laminated body.

38. The semiconductor package of claim 31, wherein the third conductive pad is positioned outside of an area between the first and second conductive pads.

39. The semiconductor package of claim 38, wherein an edge of the third conductive pad is positioned along a line connecting two end points of the first and second conductive pads closest to one another.

40. The semiconductor package of claim 31, wherein a plurality of conductive posts are formed on the chip for electrically connecting the chip to the conductive bumps.

41. The semiconductor package of claim 31, further comprising an encapsulant formed on the surface of the laminated body for encapsulating the chip and the conductive bumps.
